(19) United States
(12) Patent Application Publication
(10) Pub. No.: US 2015/0202846 A1
(43) Pub. Date: Jul. 23, 2015

(54) REFLECTIVE AND CONDUCTIVE COATINGS DIRECTLY ON PVB

(71) Applicants: Harlan J. Byker, West Olive, MI (US); Christopher D. Anderson, East Grand Rapids, MI (US); Curtis J. Liposcak, Madison, WI (US)

(72) Inventors: Harlan J. Byker, West Olive, MI (US); Christopher D. Anderson, East Grand Rapids, MI (US); Curtis J. Liposcak, Madison, WI (US)

(73) Assignee: Pleotint, L.L.C., West Olive, MI (US)

(21) Appl. No.: 14/598,725

(22) Filed: Jan. 16, 2015

Related U.S. Application Data
(60) Provisional application No. 61/928,465, filed on Jan. 17, 2014.

(51) Int. Cl. B32B 17/10; C23C 14/22; C23C 14/35; B32B 27/30

(52) U.S. Cl. CPC B32B 17/1055; B32B 27/30; C23C 14/22; C23C 14/35

(57) ABSTRACT

A directly-coated PVB film or sheet. The film or sheet includes a PVB layer that includes no plasticizer or less than about 5 weight percent plasticizer and a conductive or reflective coating. The conductive or reflective coating directly coats the PVB layer. The PVB film or sheet is includable in a laminate.

### CROSS-REFERENCE TO RELATED APPLICATIONS

This application claims priority to U.S. Prov. Pat. App. No. 61/928,465, filed Jan. 17, 2014, the entirety of which is incorporated by reference herein.

### TECHNICAL FIELD

This application relates to coatings for plastic films, and more particularly to systems and methods pertaining to reflective and conductive coatings for polyvinylbutyral films.

### BACKGROUND

Direct coating of plastic films with reflective and conductive coatings by various physical vapor deposition, (PVD), methods in high vacuum is common. However some types of plastic films are considered incompatible with these direct coating methods. Until now polyvinylbutyral, (PVB), was among the plastic films considered incompatible with these coating methods. Reflective and conductive coatings directly on PVB are useful for wide variety of applications including touch screen applications, mirror and selective mirror applications, solar cell applications, solar control applications in virtually any type of window product and electrically heated windows including heated windshields.

Of the sun's energy that reaches the earth's surface about 3% is ultraviolet radiation, (UV), about 47% is visible radiation and about 50% is infrared radiation which is mainly near infrared, (NIR) radiation. In many applications where people are looking through a transparent layer there is a desire to maintain adequate visible light transmission while minimizing both the UV transmission for its damaging effects and the NIR transmission for its potentially excessive heat load effects. This is the case in many window applications for buildings and motor vehicles.

While the definition of light might be restricted by some to the visible electromagnetic radiation that can be seen, in this disclosure the word “light” is used to include the UV electromagnetic radiation, the NIR electromagnetic radiation of the sun that reaches the earth's surface, as well as the visible portion.

UV light may be blocked by selective absorbers of the UV wavelengths of radiation somewhere in a window structure. Selective UV absorbers include certain metal oxides, metal-organic compounds, and organic UV absorbers which often serve a dual purpose as UV stabilizers for polymeric films and layers. Polymeric films and layers may be incorporated into a window structure and provide a variety of benefits. In principle, UV wavelengths could be rejected by reflection, for example with a specialized dichroic mirror, but this type of reflection effect is not commonly used in building or vehicle windows.

The NIR may be absorbed by selective absorbers of NIR or also, quite commonly, the NIR may be rejected by selective reflectors of NIR. Selective NIR absorbers that do not also absorb significant visible light are less common, but useful materials include certain organic and metal-organic dyes that may be incorporated into polymeric films and layers. These organic and metal-organic dyes often have limited stability when exposed to sunlight. Selective NIR absorbers also include metal oxides which may be incorporated into the composition of a glass substrate or as thin films on a substrate. Selective NIR absorbers also include nanoparticles of certain inorganic materials like cesium tungsten oxide, lanthanum hexaboride, or antimony tin oxide nanoparticles, which may be dispersed in a polymer matrix. Selective NIR reflectors include ultrathin metal layers, (like silver and silver alloy layers), usually antireflected by ultrathin layers of high index of refraction materials. Alternately NIR reflectors may be degenerately doped semiconductor type metal oxides like fluorine doped tin, fluorine doped zinc oxide, tin doped indium oxide (ITO), or aluminum doped zinc oxide. Alternately, NIR reflectors may be multi-layer systems of metal oxides or multiple layers polymers, both with alternating indices of refraction from layer to layer. For example U.S. Pat. No. 6,391,400 discloses multi-layer metal oxide systems as a NIR dielectric mirror on polymer films.

### SUMMARY

One embodiment of the invention is a layer of PVB which is directly-coated with one of more than one conductive coating by PVD in high vacuum.

One embodiment of the invention is a layer of PVB which is directly-coated with one or more than one reflective coating by PVD in high vacuum.

One embodiment of the invention is a layer of PVB which is directly-coated with one or more than one NIR reflective coating by PVD in high vacuum.

One embodiment of the invention is a layer of PVB which is directly-coated with one of more than one conductive coating by sputtering in high vacuum.

One embodiment of the invention is a layer of PVB which is directly-coated with one of more than one reflective coating by sputtering in high vacuum. One embodiment of the invention is a layer of PVB which is directly-coated with one of more than one NIR reflective coating by sputtering in high vacuum.

One embodiment of the invention is silver metal or silver alloy metal layer which is coated directly on a layer of PVB or a silver metal or silver alloy metal layer coated directly on an antireflecting layer which is directly-coated on a layer of PVB.

One embodiment of the invention is a stack of layers comprising silver metal and/or silver alloy metal layers that are antireflected by metal oxide layers, where the stack of layers is coated directly on a layer of PVB.

One embodiment of the invention is a layer of PVB which contains 0% to about 5% of plasticizer which is directly-coated with a one or than one conductive or reflective layer.

One embodiment of the invention is a layer of PVB which contains a plasticizer, where the plasticizer is a substituted ammonium or phosphonium salt.

One embodiment of the invention is a layer of PVB directly-coated with a NIR-reflecting layer or NIR-reflecting stack of layers where the NIR-reflecting layer or NIR-reflecting stack of layers is/are in contact with a layer of plasticized PVB.

One embodiment of the invention is a layer of PVB directly-coated with NIR-reflecting layer or NIR-reflecting stack of layers where the NIR-reflecting layer or NIR-reflecting stack of layers is/are in contact with a sheet of glass.

One embodiment of the invention is a layer of PVB directly-coated with a NIR-reflecting layer or NIR-reflecting stack of layers where the uncoated side of the directly-coated PVB is in contact with a layer of plasticized PVB.

One embodiment of the invention is a layer of PVB directly-coated with a NIR-reflecting layer or NIR-reflecting stack of layers where the uncoated side of the directly-coated PVB is in contact with a sheet of glass.

One embodiment of the invention is a layer of PVB directly-coated with NIR-reflecting layer or NIR-reflecting stack of layers sandwiched between two layers of plasticized PVB.

One embodiment of the invention is an initially plasticizer free layer of PVB directly-coated with NIR-reflecting layer or NIR-reflecting stack of layers where the NIR-reflecting layer or NIR-reflecting stack of layers is/are in contact with a layer of plasticized PVB and this interlayer forms wrinkle and distortion free glass laminates.

One embodiment of the invention is an initially plasticizer free layer of PVB directly-coated with NIR-reflecting layer or NIR-reflecting stack of layers sandwiched between two layers of plasticized PVB and this interlayer forms wrinkle and distortion free glass laminates.

One embodiment of the invention is a layer of PVB directly-coated with layers comprising silver or silver alloy layers which provide selective NIR reflection.

One embodiment of the invention is a layer of PVB directly-coated with layers comprising silver or silver alloy layers which are antireflected by carbides, silicides, borides, nitrides, oxides and oxynitrides layers or combinations or mixture thereof.

One embodiment of the invention is a layer of PVB directly-coated with layers comprising silver or silver alloy layers which provide selective NIR reflection where color suppression is provided by selective absorption in a layer of the multilayer interlayer.

One embodiment of the invention is a directly-coated PVB interlayer for use in lamination which selectively reflects NIR light.

One embodiment of the invention is a low cost safety glass window with an interlayer of the present invention which selectively reflects NIR light.

One embodiment of the invention is a low cost safety glass windshield with an interlayer of the present invention which selectively reflects NIR light.

One embodiment of the invention is a layer of PVB which is directly-coated with one or more than one reflecting layer or one or more than one electrically conductive layer by a PVD method including sputtering in high vacuum.

One embodiment of the invention is silver metal or silver alloy metal layer which is coated directly on a layer of PVB or a silver metal or silver alloy metal layer coated directly on an antireflecting layer which is directly-coated on a layer of PVB.

One embodiment of the invention is a stack of layers comprising silver metal and/or silver alloy metal layers that are antireflected by metal oxide layers, where the stack of layers is coated directly on a layer of PVB.

One embodiment of the invention is a layer of PVB which contains 0% to about 5% of plasticizer which is directly-coated with one or more than one reflecting layer or one or more than one electrically conductive layer.

One embodiment of the invention is a layer of PVB directly-coated with one or more than one reflecting layer or one or more than one electrically conductive layer where the one or more than one reflecting layer or one or more than one electrically conductive layer is/are in contact with a layer of plasticized PVB, a layer TPU, a layer of EVA or a layer of ionomer.

One embodiment of the invention is a layer of PVB directly-coated with one or more than one reflecting layer or one or more than one electrically conductive layer where one or more than one reflecting layer or one or more than one electrically conductive layer is/are in contact with a sheet of glass or a coating on a sheet of glass.

One embodiment of the invention is a layer of PVB directly-coated with one or more than one reflecting layer or one or more than one electrically conductive layer where the uncoated side of the directly-coated PVB is in contact with a layer of plasticized PVB.

One embodiment of the invention is a layer of PVB directly-coated with one or more than one reflecting layer or one or more than one electrically conductive layer where the uncoated side of the directly-coated PVB is in contact with a sheet of glass.

One embodiment of the invention is a layer of PVB directly-coated with one or more than one reflecting layer or one or more than one electrically conductive layer sandwiched between two layers of plasticized PVB, TPU, EVA or ionomer.

One embodiment of the invention is an initially plasticizer free layer of PVB directly-coated with one or more than one reflecting layer or one or more than one electrically conductive layer where the one or more than one reflecting layer or one or more than one electrically conductive layer is/are in contact with a layer of plasticized PVB and this interlayer forms wrinkle and distortion free glass laminates.

One embodiment of the invention is an initially plasticizer free layer of PVB directly-coated with one or more than one reflecting layer or one or more than one electrically conductive layer sandwiched between two layers of plasticized PVB and this interlayer forms wrinkle and distortion free glass laminates.

One embodiment of the invention is a layer of PVB directly-coated with one or more than layer comprising silver or silver alloys which provide visible light reflection or selective NIR reflection.

One embodiment of the invention is a layer of PVB directly-coated with one or more than one layer comprising silver or silver alloys which are antireflected by carbides, silicides, borides, nitrides, oxides and oxynitrides layers or combinations or mixture thereof.

One embodiment of the invention is a layer of PVB directly-coated with layers comprising one or more than one silver or silver alloys which provide selective NIR reflection where color suppression is provided by selective absorption in a layer of the multilayer interlayer.

One embodiment of the invention is a directly-coated PVB interlayer for use in lamination which selectively or predominately reflects NIR light.

One embodiment of the invention is a low cost safety glass window with an interlayer of the present invention which selectively or predominately reflects NIR light.

One embodiment of the invention is a low cost safety glass windshield with an interlayer of the present invention which selectively or predominately reflects NIR light.

One embodiment of the invention is an electrically heated safety glass windshield with an interlayer of the present invention which is directly-coated with an electrically conductive coating.

One embodiment of the invention is directly-coated PVB where the coating provides electrical heating in a laminated window.

One embodiment of the invention is directly-coated PVB in a laminate where the coating is protected by an edge seal.

One embodiment of the invention is directly-coated PVB in a laminate where the coating is protected by an edge seal provided by a picture framing method.

One embodiment of the invention is directly-coated PVB in a laminate with reduced sound transmission.

One embodiment of the invention is directly-coated PVB in a laminate that is combined with a tint band that allows for the passage of cell phone signals.

One embodiment of the invention is directly-coated PVB in a laminate where the laminate comprises a sheet of glass which is coated with an antireflection coating.

One embodiment of the invention is a coated layer of PVB directly-coated in vacuum with a conductive or reflective coating.

One embodiment of the invention is a coated layer of PVB directly-coated in vacuum with a conductive or reflective coating where the coating is prepared by PVD.

One embodiment of the invention is a coated layer of PVB directly-coated in vacuum with a conductive or reflective coating where the coating is prepared by magnetron sputtering.

One embodiment of the invention is a coated layer of PVB directly-coated in vacuum with a conductive or reflective coating where the PVB layer is free from plasticizer.

One embodiment of the invention is a coated layer of PVB directly-coated in vacuum with a conductive or reflective coating where the coating is prepared by PVD and the PVB layer is free from plasticizer.

One embodiment of the invention is a coated layer of PVB directly-coated in vacuum with a conductive or reflective coating where the coating is prepared by magnetron sputtering and the PVB layer is free from plasticizer.

One embodiment of the invention is a coated layer of PVB directly-coated in vacuum with a conductive or reflective coating where the coating reflects visible and NIR light.

One embodiment of the invention is a coated layer of PVB directly-coated in vacuum with a conductive or reflective coating where the coating selectively reflects NIR light.

One embodiment of the invention is a coated layer of PVB directly-coated in vacuum with a conductive or reflective coating where the coating has a sheet resistance between 0.01 and 1000 ohms per square.

One embodiment of the invention is a coated layer of PVB directly-coated in vacuum with a conductive or reflective coating where the layer is the interlayer or part of the interlayer that bonds two sheets glass together to form a laminate.

One embodiment of the invention is a coated layer of PVB directly-coated in vacuum with a conductive or reflective coating where the layer is the interlayer or part of the interlayer that bonds two sheets glass together to form a laminate where one of the glass sheets has an AR coating.

One embodiment of the invention is a coated layer of PVB directly-coated in vacuum with a conductive or reflective coating where the layer is the interlayer or part of the interlayer that bonds two sheets glass together to form a laminate where the laminate has an edge seal.

One embodiment of the invention is a coated layer of PVB directly-coated in vacuum with a conductive or reflective coating where the layer is the interlayer or part of the interlayer that bonds two sheets glass together to form a laminate where the laminate is used in a window for a motor vehicle or a building.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where an adhesive layer comprises a plasticizer, stabilizer or a visible light absorber.

One embodiment of the invention is a coated layer of PVB directly-coated in vacuum with a conductive or reflective coating where the coated side of the layer is in contact with a sheet of glass or a coating on a coated sheet of glass.

One embodiment of the invention is a coated layer of PVB directly-coated in vacuum with a conductive or reflective coating where the uncoated side of the layer is in contact with a sheet of glass.

One embodiment of the invention is a coated layer of PVB directly-coated in vacuum with a conductive or reflective coating where the coated side of the layer is in contact with an adhesive layer.

One embodiment of the invention is a coated layer of PVB directly-coated in vacuum with a conductive or reflective coating where the uncoated side of the layer is in contact with an adhesive layer.

One embodiment of the invention is a coated layer of PVB directly-coated in vacuum with a conductive or reflective coating where the coated side of the layer is in contact with an adhesive layer where the adhesive layer is selected from EVA, TPU, ionomer, silicone or PVB.

One embodiment of the invention is a coated layer of PVB directly-coated in vacuum with a conductive or reflective coating where the uncoated side of the layer is in contact with an adhesive layer where the adhesive layer is selected from EVA, TPU, ionomer, silicone or PVB.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where there of two adhesive layers that are different in thickness from each other.

One embodiment of the invention is a coated layer of PVB directly-coated in vacuum with a conductive or reflective coating where the layer is the interlayer or part of the interlayer that bonds two sheets glass together to form a laminate where the sheets of glass are different in thickness from each other.

One embodiment of the invention is a coated layer of PVB directly-coated in vacuum with a conductive or reflective coating where the coating is selected from fluorine doped tin, fluorine doped zinc oxide, ITO, or aluminum doped zinc oxide, silver, silver alloys, aluminum, chromium, rhodium and combinations thereof.

One embodiment of the invention is a coated layer of PVB directly-coated in vacuum with a conductive or reflective coating where the coating comprises silver or a silver alloy and a carbide, silicide, boride, nitride, oxide or oxynitride.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where an adhesive layer comprises a green light absorber.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where an adhesive layer comprises absorbers of red and blue light.

One embodiment of the invention is a coated layer of PVB directly-coated in vacuum with a conductive or reflective coating where the layer is the interlayer or part of the interlayer that bonds two sheets glass together to form a laminate where the PVB directly-coated in vacuum is bonded to a glass sheet in picture frame fashion with an adhesive layer.

One embodiment of the invention is a coated layer of PVB directly-coated in vacuum with a conductive or reflective coating where the conductive coating provides a means of resistive heating.

One embodiment of the invention is a coated layer of PVB directly-coated in vacuum with a conductive or reflective coating where the conductive coating provides a current collector for a photovoltaic panel.

One embodiment of the invention is a coated layer of PVB directly-coated in vacuum with a conductive or reflective coating where the conductive coating provides touch screen sensing.

One embodiment of the invention is a coated layer of PVB directly-coated in vacuum with a conductive or reflective coating where the reflective coating provides reflection for a solar concentrator.

One embodiment of the invention is a coated layer of PVB directly-coated in vacuum with a conductive or reflective coating where the reflective coating provides reflection for viewing mirror.

One embodiment of the invention is a coated layer of PVB directly-coated in vacuum with a conductive or reflective coating where the coating selectively reflects NIR light where the coating that selectively reflects NIR light is combined in an interlayer with a tint band for a windshield.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where an adhesive layer has a smooth side and textured side.

One embodiment of the invention is a coated layer of PVB directly-coated in vacuum with a conductive or reflective coating where rein the layer is the interlayer or part of the interlayer that bonds two sheets glass together to form a laminate where the laminate comprises an interlayer with one or more than one adhesive layer where an adhesive layer has a smooth side and textured side where the textured side of the adhesive layer has an R_{z} value between 10 microns and 150 microns.

One embodiment of the invention is a coated layer of PVB directly-coated in vacuum with a conductive or reflective coating where the layer is the interlayer or part of the interlayer that bonds two sheets glass together to form a laminate where the laminate comprises an interlayer with one or more than one adhesive layer where an adhesive layer comprises an additive selected from a UV absorber, a UV stabilizer, a hindered amine light stabilizers, an antioxidants, a thermal stabilizers, an adhesion promoting agent and an adhesion inhibiting agent.

One embodiment of the invention is a laminate including a coated layer of PVB directly-coated with a conductive or reflective coating, where the laminate does not include a layer of PET film or other carrier layer for the coating, other than the PVB layer.

One embodiment of the invention is a coated layer of PVB directly-coated in vacuum with a conductive or reflective coating where coated side is in contact with a stiff layer selected from a sheet of glass, the coated side of a sheet of glass, a layer of PVB without plasticizer.

### BRIEF DESCRIPTION OF THE DRAWINGS

FIG. 1 shows transmission spectra for unlaminated and laminated directly-coated PVB. in accordance with embodiments of the invention.

FIG. 2 shows transmission spectra for directly-coated PVB bilayers laminated with glass, in accordance with embodiments of the invention.

FIG. 3 is a cross-sectional schematic view of an embodiment of a directly-coated PVB bilayer laminated with glass in a “picture frame” configuration.

FIG. 4 is an expanded cross-sectional schematic view of an embodiment of a directly-coated PVB bilayer laminated with glass.

FIG. 5 is an expanded cross-sectional schematic view of an embodiment of a directly-coated PVB bilayer laminated with glass with acoustic deadening character.

### DETAILED DESCRIPTION

Conductive coatings applied directly on PVB of the inventions disclosed herein may be doped semiconductor type metal oxides, thin metal layers, and/or thin metal layers used in conjunction with high index of refraction dielectric layers. These conductive coatings are useful in capacitive sensing in touch screen panels and may be patterned by lithographic or other techniques to provide selective sensing. These conductive coatings may be used for electromagnetic interference (EMI) shielding. These conductive coatings may be useful for resistive heating applications including heated windshields for motor vehicles where the conductive coated applied directly to PVB may be used alone or in conjunction with other conductive coatings. These directly applied to PVB conductive coatings may be used as the current collector or part of the current collector of a solar cell array as the conductive side may be placed in intimate contact with a solar cell array or the grid pattern of the current collector of a solar cell array. Useful conductive coatings may be partially transparent to light or reflective of visible and/or NIR light. Useful conductive coatings of the present invention have a sheet resistance between 0.01 and 1000 ohms per square as coated directly on PVB. Useful reflective coatings have visible reflectance between 45% and 90% and selective NIR reflective coating have NIR reflectance between 35% and 90% with visible reflectance between 2% and 20% as coated directly on PVB.

For many window applications, selective absorbers and reflectors predominantly absorb or reflect in the UV and/or NIR, but most absorb and/or reflect some visible light as well. Maximizing the visible light transmission, minimizing visible light reflection and maintaining a neutral color appearance for the transmitted and reflected visible light is often a challenge. That challenge is addressed in this disclosure, including means for color suppression of the visible light reflected and transmitted.

NIR reflective coatings for windows may be coated directly on glass substrates or may be coated onto plastic substrates. Thin plastic substrates with NIR reflective coatings may be suspended by a frame to form a window pane, typically as the center pane of a triple pane window in which the outer panes are made of glass. Thin plastic substrates with NIR reflective coatings may also be laminated between sheets of glass, typically with additional layers which provide adhesion between the coated plastic substrate and the glass sheets. Commonly used additional layers which provide adhesion include ethylene vinyl acetate, (EVA), poly(vinyl butyral), (PVB), silicone, thermoplastic polyurethanes, (TPU), and ionomeric polymers like poly(ethylene-co-methacrylic acid) layers which often incorporate ions such as lithium, sodium, or zinc.

For motor vehicle windows, there is a particularly strong desire to provide good visibility through high visible light transmission and yet minimize UV and especially minimize NIR or heat load from sunlight. NIR reflection is often a preferred method of minimizing heat load from sunlight. However the windows, including windshields, of many motor vehicles are curved, and this presents challenges for providing NIR-reflecting coatings directly on the glass. The glass may be coated when it is flat and then bent or slumped, which is difficult because the NIR-reflecting coating must survive the heating and subsequent bending or slumping process without too much loss in general optical quality, too much loss in NIR reflectivity, or too much increase in visible light absorption or reflection. Alternately, the glass may be bent or slumped first, and then be coated with NIR-reflecting coatings. This strategy requires a challenging coating process or method. Coating processes or methods, like physical vapor depositions in vacuum, are typically line of sight deposition processes which make uniform coatings difficult with flat targets and curved or bent glass, especially with the variety of curvatures and compound bends typical of curved or bent glass.

Motor vehicle windshields are often made up of two sheets of glass laminated together with a polymer or plastic interlayer. The interlayer may be a single polymer layer or may be made up of multiple polymer layers. The laminated glass structures may also be used in sunroofs, panoramic roofs, other roof windows, side windows and backlights of motor vehicles like trucks, boats, planes, trains, heavy equipment, and automobiles. This provides the opportunity to incorporate a plastic layer in the lamination structure that has been coated with NIR-reflecting coatings. By far, the most common substrate which is coated with NIR-reflecting coatings is poly(ethylene terephthate) (PET). The coated PET is typically sandwiched between two adhesive layers such as layers of PVB or other polymer layers that provide adhesion between the coated substrate and the glass and the adhesive layers may also provide some safety character to the window. In order to provide the proper shrink characteristic for use in lamination structures, the PET is often biaxially oriented resulting in significant birefringence which manifests itself is an undesirable rainbow reflection especially when viewed through polarized sunglass lenses. In addition, PET lacks the flexibility to bend without wrinkling when bent around the complex curves typical of glass in motor vehicle applications.

This is reinforced by U.S. Pat. No. 4,973,511 which discloses: “Despite the exercise of great care in effecting this bonding process, it is not presently possible to produce a composite solar/safety film 24 that does not exhibit wrinkling to the extend [sic] that the optical properties of the final windshield assembly are adversely affected. Thus, according to this invention the relationship between substrate wrinkling and visible light reflection contribution from the solar film is recognized. More specifically, the adverse optical effects of these wrinkles are masked by controlling to two percent or less the visible light reflection contribution of the solar film to the overall laminate. In this manner, the wrinkles are not eliminated but rendered less visible to the human eye since the reflection contribution of substrate layer 16 containing the wrinkles is purposely controlled below a predetermined visibility threshold.”

Also, coated PET sandwiched between two layers of PVB, or the like, often exhibits an unsightly “orange peel” or “apple sauce” appearance in the small visible reflection that is common in NIR-reflecting layers and is exacerbated by refractive index mismatch between PET and PVB. This mismatch is eliminated when the directly-coated PVB of the present invention is sandwiched between layers of PVB. Thus, all of the current means of proving NIR reflection for windshields are complicated, expensive, and/or provide undesirable visual appearance. All of these undesirable issues only become more pronounced as the complexity of the window curvature increases. Thus despite suggested methods of addressing these heat load problems in the early 1970's, for example in U.S. Pat. No. 3,718,535, this technology has been limited to select applications and has not made it to really widespread use in motor vehicles.

The invention disclosed herein address these issues. One embodiment of the invention is a layer of PVB which is directly-coated with a NIR-reflecting layer or with a stack or plurality of NIR-reflecting layers. While U.S. Pat. No. 6,391,400 discloses the hypothetical concept of depositing NIR-reflecting layer on PVB there is no indication that such a feat was ever attempted or achieved. Also, an earlier disclosure in U.S. Pat. Nos. 3,962,488 and 4,782,216 expressly concluded “On the other hand, polyurethanes and polyvinyl butyral are too soft and extensible for vacuum coating.” In addition U.S. Pat. No. 4,226,910 fails to mention PVB in a long list of directly coatable polymers: “Most (if not all) of the presently commercial solar energy control sheets utilize support layers of polyester foil (biaxially oriented polyethylene terephthalate), which offers the combined advantages of strength, flexibility, clarity and moderate cost. Other polymers which can be made into functional support foils include polyvinyl fluoride, polyvinylidene fluoride, polycarbonates, polystyrene, polymethyl methacrylate, polyimides, polyamides, ionomers, etc., as well as esters and mixed esters of cellulose.”

PVB is formally described as the copolymer, poly(vinyl butyral-co-vinyl alcohol-co-vinyl acetate), but is often referred to simply as poly(vinyl butyral) or PVB. PVB is hygroscopic and removal of moisture requires significant effort. PVB is normally supplied as a resin powder or as a highly plasticized interlayer or sheet or film. As a practical matter, it is understood in the art that commercialized PVB films, sheets or foils contain plasticizer. Normally, films which are plasticized are virtually impossible to use as substrates for physical vapor deposition in high vacuum due, at a minimum, to softness, extensibility and pliability. In addition, vacuum deposition is problematic because of the outgassing of volatile impurities and/or the plasticizer itself, unless the plasticizer has very low volatility, and may thus be considered “non-volatile. We have discovered that PVB film or sheet which contains little or no volatile material, including little or no plasticizer, may be directly-coated by physical vapor deposition in high vacuum. “Little volatile material” means less than 5 weight percent volatile materials. No volatile material means 0 weight percent volatile material. In particular we have discovered that low plasticizer PVB film or sheet may be coated with conductive and reflective layers including a selective NIR-reflecting layer or layers by physical vapor deposition in high vacuum. Preferably, the PVB film or sheet has no plasticizer or no volatile plasticizer. No plasticizer means 0 weight percent plasticizer and little plasticizer means about 5 weight percent or less. A low volatility plasticizer is a plasticizer that causes little or no interference with the vacuum deposition process by vaporized plasticizer. Preferred low volatility plasticizers include salts such a substituted ammonium and phosphonium salts, which may be considered “non-volatile.” The substitutions include alkyl, aryl and aralkyl groups, including tetraalkylammonium and tetraalkylphosphonium salts. In one embodiment, the PVB film or sheet is free of high volatility materials, where “high volatility materials” are defined as materials with a vapor pressure greater than about 1 mmHg at 20° C. In another embodiment, the PVB film or sheet is also essentially free of low volatility materials, where “low volatility materials” are defined as materials with a vapor pressure between zero and about 1 mmHg at 20° C., and where “essentially free of low volatility materials” means less than 5 weight percent, and preferably 0 percent, low volatility materials. In one embodiment, the PVB film or sheet may include low volatility materials, for example low volatility/non-volatile plasticizers such as substituted ammonium and/or phosphonium salts, in amounts greater than 5 weight percent. PVB with NIR reflecting coating or coatings transferred to the PVB is described in U.S. Pat. No. 6,365,284. However the lack of directly applying the coating or coatings to the PVB and difficulty of transferring the coating or coatings from a carrier layer to the PVB were significant drawbacks.

A preferred method of producing PVB layers, films, or sheets with little or no plasticizer is by the extrusion cast method. The PVB resin alone or PVB resin along with low volatility additives and, optionally, low volatility plasticizers is fed into the screw flights of an extruder. In one embodiment, a low volatility plasticizer has a vapor pressure between zero and about 1 mmHg at 20° C. In the extruder, the PVB resin is melted to form a viscous liquid which passes through the die and exits the die as a viscous liquid film or sheet. The film or sheet normally exits the die into a water bath or onto a chill roller where the viscous liquid cools and solidifies. Any stretching of the viscous liquid film or sheet during the cooling or solidification process may introduce residual stress in the film or sheet. A PVB film or sheet with too much residual stress will tend to shrink on reheating.

Single screw extruders are poor at mixing ingredients but good at conveying materials. Thus, a single screw extruder can directly feed a film or sheet die with the relatively consistent pressure required to produce reasonably uniform or consistent gauge in the machine direction. Twin screw extruders mix materials well but do a poor job of conveying materials. However, a gear pump may be added to the end of a twin screw extruder to take the output of the extruder and pump it with consistent pressure to the film or sheet die. This way, a uniform or consistent gauge film or sheet may be produced directly with a twin screw extruder. Either single screw or twin-screw extruders may be used for the extrusion cast production of low or no plasticizer PVB film or sheet PVB film or sheet with only very low volatility constituents.

Another preferred method of producing PVB layers, films, or sheets with little or no plasticizer is by the solvent cast method. In one embodiment, PVB layers may be solvent cast using solvents such as alcohols, THF, and/or toluene. While production by this method is less cost effective as compared to extrusion casting, solvent casting produces PVB layers, films, or sheets with very low residual stress. In the solvent cast process, PVB resin is dissolved in a solvent and cast, often through a slot die, onto a carrier sheet or a belt and passed through an oven to remove solvent and leave behind a layer which is stripped from the sheet or belt. Alternatively, the PVB may be formed into an emulsion or latex with water, and this dispersion is cast, often through a slot die, onto a carrier sheet or a belt and passed through an oven to remove water and allow the PVB to coalesce into a layer which is stripped from the sheet or belt.

If there is residual stress in the PVB film or sheet that is used as the interlayer or part of the interlayer, the PVB film or sheet is likely to shrink during the glass lamination process. In one embodiment, a PVB film having minimal residual stress shrinks less than 2% in the length and/or width direction(s) upon heating of the film to temperatures above 80° C. Excess shrinkage may result in no interlayer or partial interlayer around the edge of the laminate, and/or the interlayer may take on a wrinkled, crackled, or puckered appearance in some portion of the main area of the laminate. This is especially true if the interlayer comprises a NIR reflector coated PVB with little or no plasticizer, in which the PVB film has residual stress.

Remarkably, it has been discovered that when a bilayer or a trilayer polymer film or sheet is made by bonding together a directly-coated layer of PVB, which has little or no plasticizer with some residual stress, and one layer or two layers of plasticized PVB and when the bilayer or trilayer is stored for a brief period of time, the stress in the PVB with little or no plasticizer is relaxed. Without wishing to be bound to the theory, this is presumably due to plasticizer diffusing from the plasticized PVB into the PVB with little or no plasticizer or due to strong adhesion between these layers. Alternatively, stress may be avoided altogether by careful extrusion, or stress may be relieved by annealing the film after extrusion. It is preferred to bond the directly-coated PVB to another layer of PVB or to sandwich the directly-coated PVB between two layers of PVB, but the directly-coated PVB with little or no plasticizer may also be bonded to a layer or sandwiched between layers of other materials, for example thermoplastic polyurethanes (TPUs), silicone, EVA, ionomeric polymers, and the like. The coated PVB and the plasticized PVB or layers of other materials may be formed into a bilayer or trilayer in an encapsulation process like that described in U.S. Pat. No. 6,365,284, the entirety of which is hereby incorporated by reference herein, or by other means.

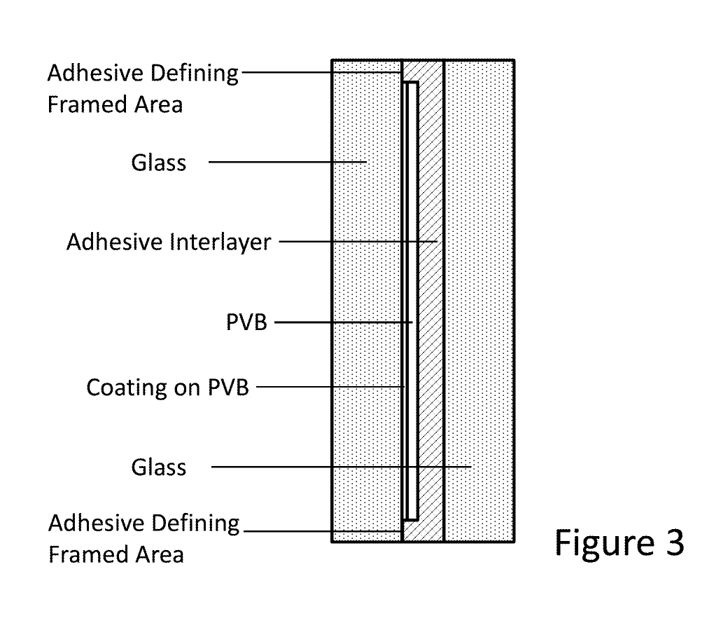

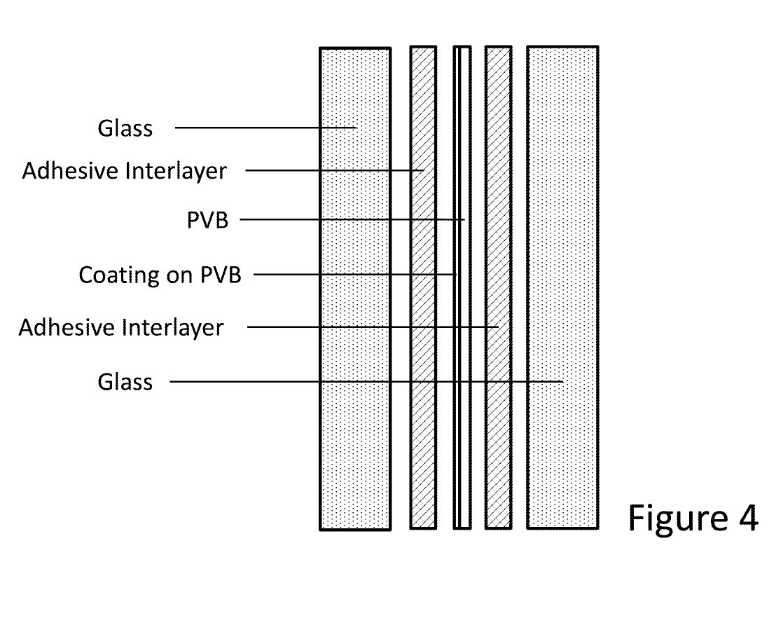

The term “directly-coated,” in one embodiment, means that the conductive and/or reflective coatings are coated by vapor deposition directly on the PVB film without transfer from an intermediate film such as PET. It has been discovered that bonding the directly-coated PVB layer to another relatively stiff layer helps preserve the optical quality of the vacuum-deposited coating and helps prevent cracking, crazing and wrinkling within the reflective layers. Accordingly, this may be accomplished by bonding the directly-coated PVB layer directly to a sheet of glass, either with the coated side or with the uncoated side of the directly-coated PVB layer in contact with the glass. In some cases, with reference to FIG. 3, this bonding directly to glass is accomplished by placing the coated side of the directly-coated PVB in contact with the glass and under-sizing the directly-coated PVB sheet with respect to the size of the sheet of glass. Then, an adhesive layer of PVB, TPU, EVA, or the like, that is similar in size to the glass sheet is placed on top of the directly-coated PVB. A second sheet of glass is placed on this assembly and the lamination is completed by conventional means. Thus, the directly-coated PVB has a “picture frame” of adhesive layer helping to maintain the contact between the glass and coated side of the directly-coated PVB. Alternately, in one embodiment, the laminate may be constructed in accordance with the layer structure depicted in FIG. 4.

Another preferable means of preserving the optical quality of the conductive or reflective coatings is to bond the directly-coated PVB layer on the coated side to a stiff layer of PVB which may also have little or no plasticizer. This bilayer of stiff PVB films or sheets, with the integrity of conductive or reflective coating protected between them, may be bonded to a sheet of glass or between sheets of glass by itself or with one or more than one layer of PVB or other interlayer material.

The PVB layer that is directly-coated may contain various stabilizers and additives that have little or no volatility (e.g., with a vapor pressure less than about 1 mmHg at 20° C.) or which at least do not interfere with the direct coating process. These additives include stabilizers like UV absorbers, UV stabilizers, hindered amine light stabilizers, antioxidants, thermal stabilizers, adhesion promoting agents, and/or adhesion inhibiting agents and the like. When the directly-coated PVB layer is bonded to another layer of PVB or is encapsulated between two other layers of PVB, those layers of PVB may contain plasticizers, antioxidants, thermal stabilizers, absorbers including UV absorbers, stabilizers, UV and light stabilizers including benzotriazoles, benzophenones cyanoacrylates and hindered amines, adhesion promoters, adhesion inhibitors, coloring agents, selective UV, NIR and visible light absorbers including color suppressing agents and/or a variety of other additives known in the art PVB interlayers. These additives and plasticizers may enter the directly-coated PVB layer from the other layers that are placed in contact with the directly-coated PVB layer after it is coated. This allows the coated PVB layer to eventually contain beneficial additives and even materials that would have been too volatile to be present during the vacuum deposition process.

Most polymer layers, films, or sheets, including those comprising PVB, are subject to some environmental degradation. Coating directly on PVB may also be susceptible to corrosion or other degradation. Thus, stabilization of polymer systems and coatings by preventing or minimizing degradation due to heat and/or light induced reactions of materials is desirable. The best approach to stability is to find materials that are inherently high in stability. It is also effective to provide barriers and seals, including edge seals, to protect against the ingress of things that contribute to degradation, especially oxygen, water, and ultraviolet light. The “picture framing” process or method described above is particularly effective in this regard. Another important approach is to provide additives which help deal with degradation processes via competitive light absorption, tying up degradation products. and/or inhibiting further degradation processes.

Important stabilizers that may be added are antioxidants and heat stabilizers. Preferred are free radical inhibitors such as the hindered phenols. Some useful antioxidants and thermal stabilizers include 2,6-di-tertbutyl-4-methylphenol (BHT), IRGANOX® 245, IRGANOX® 1010, IRGANOX® 1035, IRGANOX® 1076 and IRGANOX® 5057. The IRGANOX® materials are available from BASF.

Photodegradation of polymers and coatings, especially from short wavelength light, (like UV and short wavelength visible light), is minimized or eliminated by short wavelength absorbing additives, added to the polymer of interest. These additives are sometime called “UV absorbers” and may be divided into two groups. The first group includes materials which simply absorb short wavelength light. Examples of this group are ethyl-2-cyano-3,3-diphenylacrylate and (2-ethylhexyl)-3,3-diphenylacrylate available from BASF as UVINUL® 3035 and UVINUL® 3039 respectively. The second group involves absorbers of short wavelength light which also function as stabilizers against the propagation of degradation initiated by light exposure. Examples of materials of this group are hydroxybenzophenones, hydroxyphenylbenzotriazoles and hydroxyphenyltriazines. Examples of these materials sold under the trade names: TINUVIN® P, TINUVIN® 213, TINUVIN® 234, TINUVIN®326, TINUVIN® 327, TINUVIN® 328, TINUVIN® 400, TINUVIN® 405 and TINUVIN® 479. These materials are available from BASF. Also useful are nickel salt stabilizers like dialkyldithiocarbamates, which are good UV absorbers even though they are bit yellow in polymer films.

Also effective in helping stabilize polymer systems are light stabilizers that themselves are not very effective at absorbing short wavelength light. Representative examples of materials of this type are hindered amine light stabilizers, (HALS). Useful HALS include TINUVIN® 144, TINUVIN® 765 and TINUVIN® 770 available from BASF.

Any or all of the above stabilizers may be added to any of the polymer layers in the present invention.

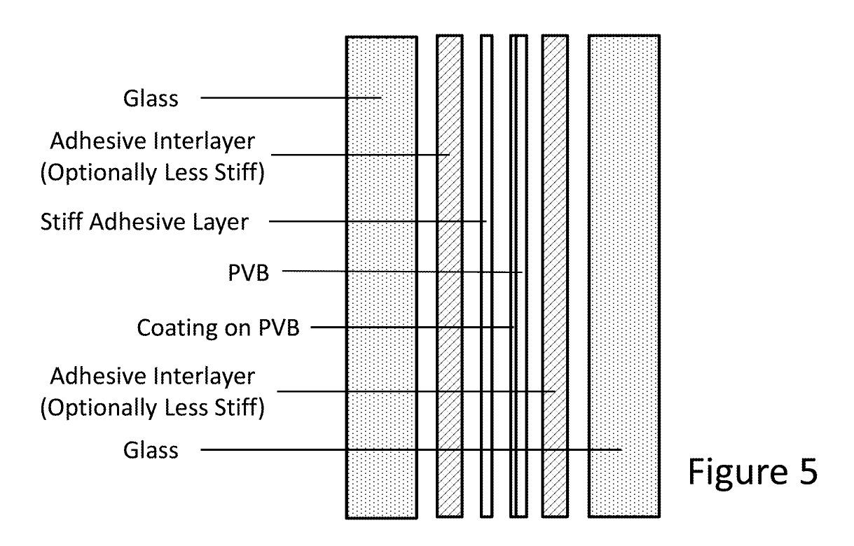

U.S. Pat. No. 7,968,186 discloses “Glass laminates comprising acoustic interlayers and solar control films.” With reference to FIG. 5, the PVB directly coated with conductive and/or reflective coatings of the present invention advantageously provides a stiff, little or no plasticizer, layer(s) for an enhanced version of this acoustic interlayer application. Acoustic interlayer often consists of a layer of less-stiff PVB or other interlayer material, which optionally comprises lower in molecular weight and/or higher plasticizer content polymer, sandwiched between two layers of stiff polymer, which optionally comprise higher in molecular weight and/or lower plasticizer polymer. Alternately, a stiff polymer layer may be sandwiched between two less-stiff polymer layers. For example, a layer of stiff directly-coated PVB may be sandwiched between two layers of soft or less-stiff TPU, and the TPU layers may be of different thicknesses from each other to help disrupt sound transmission, especially when this trilayer is used to laminate together two sheet of glass which preferably also have different thicknesses from each other. In general, sound traveling through a laminate with layers of alternating stiffness and thicknesses is subject to excellent sound reduction or attenuation. The no or low plasticizer PVB may be used as one or more of the stiff layers of the acoustic interlayer and provide a stiffness and sound reduction capability not previously realized in acoustic interlayers.

The typical glass lamination processes involves placing a film or sheet of interlayer on a first sheet of glass and then placing the second sheet of glass on the interlayer. This is followed by placing this prelaminate assembly in a flexible vacuum bag, and pulling a vacuum inside the bag so that atmospheric forces press on the bag and hence the prelaminate. This is followed by heating the vacuum-bagged assembly either at atmospheric pressure or at elevated pressure in some kind of chamber like an autoclave. Alternatively, the prelaminate assembly is heated and passed through one or more than one nip roller(s) which largely de-airs the prelaminate, tacks the interlayer to the glass, and forms a seal between the interlayer and glass around the perimeter of the assembly. This de-aired, tacked, and perimeter-sealed assembly is then heated at atmospheric pressure, or preferably is heated at elevated pressure, typically in an autoclave which is typically pressurized and then heated which further increases the pressure in the autoclave. In some cases it is preferred that the interlayer surfaces that come in contact with the glass sheets have a somewhat rough texture to more effectively allow air to be removed without trapping large bubbles during the vacuum bagging and heating process or during the nip roll-tack process. Interlayer roughness (R_{z}) can be determined directly with a profilometer, such as a POCKET SURF® PS1 from Mahr Federal Inc., Providence, R.I. In one embodiment, the roughness of the interlayer surface adhered to the glass is about 10 microns to about 150 microns. While very small bubbles may be present after tacking, these tend to disappear during subsequent exposure to heat and pressure as the tiny amount of gas dissolves into the interlayer material during the process.

The somewhat rough texture on the interlayer may be provided by melt fracture of the PVB film or sheet as it exits the film or sheet die or by embossing the PVB film or sheet after it exits the die. Alternatively, the texture may be provided by some combination melt fracture and embossing. For the present invention it is preferred that the directly-vacuum-coated PVB layer with little or no plasticizer be very smooth with little or no texture, or that this PVB layer have a very fine micro texture. The R_{z} value should be between 0 and about 10 microns. It is also preferred that the plasticized PVB that is combined with the coated PVB with little or no plasticizer have a smooth side and a textured side, where the smooth side is placed in contact with the coated PVB so that the textured side may be placed in contact with a sheet of glass. If the coated PVB is sandwiched between two adhesive layers, it is preferred that both adhesive layers have a smooth side and a textured side and that both smooth sides be used to sandwich the coated PVB so that both textured sides are available to contact sheets of glass. Alternatively, the adhesive layer or layers may have a side with normal, somewhat rough texture and a side with a micro texture. If there is a micro texture in the directly-coated PVB layer or in the adhesive layer or layers, then when these layers are combined, the micro texture serves to break up the small amount of specular visible reflection associated the conductive or reflective coating that was coated directly on PVB. When properly done, the diffuse reflection from the micro texture will not appear as an objectionable amount of haze, and the appearance of the specular reflection will be reduced.

A key achievement of the present invention is a NIR-reflecting interlayer for use in normal lamination procedures which forms essentially wrinkle and distortion-free glass laminates without defects or undesirable optical effects.

Preferred NIR-reflecting layers are silver metal and silver metal alloys. Some of the preferred NIR-reflecting layers may be referred to as Fabry-Perot interference filters. The silver metal and silver metal alloys are preferably placed between antireflecting layers. Preferred antireflecting layers are carbides, silicides, borides, nitrides, oxides, and oxynitrides of a metal or mixture of metals. For example, the antireflecting layers may include tungsten oxide, indium oxide, tin oxide, zinc oxide, tin doped indium oxide, titanium dioxide, bismuth oxide, aluminum oxide, zirconium oxide, silicon nitride, chromium nitride, zirconium nitride, silicon oxynitride, silicon aluminum oxynitride, and combinations, multiple layers and mixtures thereof. Combinations of antireflecting layers refer to having more than one type of antireflecting layer in a stack. For example, on one side of a silver or silver alloy layer may be placed one type of metal oxide and on the other side of the silver or silver alloy layer may be placed another type of metal oxide. Alternatively, on one side of a silver or silver alloy layer may be placed a metal nitride and on the other side a metal silicide. Multiple layers means that an antireflecting layer contains for example a layer of oxide and a layer of oxynitride. A mixture refers to having more than one type of material in a single layer, such as having a nitride and a boride or an oxide and a carbide in the same layer. Thin protection layers and sacrificial protection layers like tin, indium, rhodium, platinum, gold, aluminum, nickel, titanium and zinc metal and alloys like nichrome may also be used as layers deposited on the silver, silver alloy or the antireflection layers. In one embodiment, alloys of silver are alloys of silver with gold and in another embodiment they are alloys of silver with copper.

While selective NIR reflectors are preferred in solar control window applications, preferred reflectors which reflect visible and NIR light are layers of metal such as silver, silver alloys, aluminum, chromium, rhodium, and combinations thereof. These reflectors are thicker than those that selectively reflect NIR light. Useful visible light reflecting coatings of the present invention include mirrors for solar concentrators and mirrors for general reflection viewing like bathroom mirrors.

Preferred deposition methods for a conductive, visible-reflecting and selective NIR-reflecting layer or for a stack of layers which provide conductivity or reflection are physical vapor deposition (PVD) methods in vacuum. PVD methods include, among others, electron beam evaporation, thermal evaporation, and sputtering. Especially preferred is magnetron sputtering in the presence of small amounts of argon, krypton, and/or xenon, with or without reactive gases such as oxygen or nitrogen. Some coatings like silver and silver alloys are normally deposited without reactive gas, and antireflecting coating(s) are deposited with or without reactive gas depending on the type of antireflecting coating(s) involved and the type of PVD involved. The preferred method is roll-to-roll coating where a roll of PVB with little or no plasticizer or no volatile plasticizer is placed in vacuum and is passed by one or more than one deposition targets, and then connected to a take up roll. The PVB layer is then fed from one roll and taken up by the other roll, and as the PVB passes by the target(s), it is coated with one or more than one layer. Preferably, the PVD or sputtering is controlled such that the polymer substrate temperature remains under about 100° C. during the deposition process, and more preferably remains under about 75° C. This low temperature process has been discovered to be desirable for PVB. The direct coating of high quality reflecting and/or electrically conductive coatings on PVB is a remarkable achievement of the present invention.

During this type of deposition, it is critical that volatile materials not come out of the PVB and interfere with the deposition process. Materials to be specifically avoided are water, volatile plasticizers with even a small amount of volatility, reactants, byproducts or impurities from the manufacture or extrusion of the PVB like butyraldehyde or 2-ethylhexenal. Volatiles may be avoided by starting with relatively pure resin followed by extrusion under conditions where there is little or no decomposition of the PVB. Alternatively, or in addition, the PVB may be dried and volatiles may be removed by storing the PVB layer under vacuum optionally over desiccants or absorbents like activated charcoal. A preferred method of moisture removal from PVB sheets or films is a desiccating interleave as disclosed in co-pending U.S. patent application Ser. No. 12/816,635, filed Jun. 16, 2010, the entirety of which is hereby incorporated by reference herein. When PVB or other hygroscopic films or sheets are interleaved with a desiccating interleave, the moisture content is reduced to and maintained at a very low level. The preferred water content for the PVB layer, prior to deposition, is less than about 0.5 weight percent as determined by Karl Fischer titration.

The PVB layer to be directly-coated in vacuum or other layers that are placed in contact with the directly vacuum coated PVB layer may optionally contain one or more than one color-suppressing agent. This is of interest when the directly-coated PVB has some undesirable visible light absorption and/or reflection which gives rise to a color appearance to the transmitted and/or reflected light. In the case of selective NIR reflective coating(s), they are often optimized for maximum visible transmission based on the human eye sensitivity. Maximum visible transmission often results in a minimum reflection in the green portion of the spectrum and slightly higher reflection in the blue and red regions of the spectrum. The blue-red or purple or magenta appearance of the reflection is suppressed by placing one or more than one blue and red or purple or magenta selective absorbers in a layer that is in contact with the coated PVB. The layer with these blue and red or purple or magenta absorbers is placed between the observer and the coating on the directly-coated PVB. In most windshield and motor vehicle applications, the adhesive layer with these absorbers is placed in contact with the exterior sheet of glass, and the directly-coated PVB is placed in contact with the other side of the absorber containing an adhesive layer. Alternately or additionally, in order to suppress, for instance, a slight green appearance of the transmitted light, a selective green absorber is placed in an adhesive layer that is in contact with the coated PVB. A preferred selective absorber of green light is KEYSTONE™ Red 2G available from Keystone Aniline Corporation of Chicago, Ill. The green absorber, if used, is preferably placed in the adhesive layer that contacts the interior sheet of glass of a motor vehicle.

A window with a visible light transmitting interlayer of the present invention has even higher light transmission when the glass surfaces of the laminate that are in contact with air are coated with antireflection coating(s) (AR coating(s)). One or more than one AR coating also helps compensate for the small but undesirable visible reflection that comes from the directly-coated PVB layer. For windshields and other curved glass windows, certain AR coating(s) may be provided on the glass prior to bending the glass. A preferred low reflection or AR coating on the glass is the type that is provided on the glass float line by chemical vapor deposition while the glass is being made into sheet form. Since the PVB interlayer is a good index of refraction match to the glass, only the exterior surfaces of the glass require a low reflection or AR coating in this embodiment of the invention.

A challenge with most reflecting and/or electrically conductive layers in windows is the blocking of electronic signals like those for cell phones or radar detectors. However, for motor vehicle windshields there is also a desire to provide a shade band near the top of the windshields and it is often blue in color. In the present invention these two issues are addressed by placing the NIR-reflecting layer over most of the windshield area and a tint layer near the top of the windshield. The tint layer optionally contains NIR absorbing materials like nanoparticles or dyes. The tinted, NIR absorbing layer does not have electronic signal blocking characteristics so these signals are free to leave or enter the vehicle in this area. The combination of NIR-reflecting and tinted, optionally NIR absorbing, areas may be provided in the encapsulation process where a roll of NIR reflector coated PVB and a layer of tinted, optionally NIR absorbing PVB are placed side by side or butted up against one another. Adhesive interlayer is then bonded on either side of the reflecting and absorbing middle layers to provide a trilayer ready to be used to laminate together sheets of glass. The visible tinting and the NIR absorption may be provided by various dyes, pigments and nanoparticles known in the art. Of particular interest are nanoparticles of cesium tungsten oxide, which naturally provide a blue color to a tint band. The combination provides good solar control by reflecting NIR over most of the area, and absorbing some visible and NIR near the top the windshield, while freely transmitting radio frequency and other electronic signals like cell phone signals.

While the main feature of the present invention is a unique method of providing reflecting and conducting coatings including selectively NIR-reflecting coatings, it should be understood that interlayers with reflecting and conducting coatings may also have thermochromic or photochromic activity and/or UV, visible or NIR absorbers in the layers which provide protection, functional tinting, and/or additional solar control.

Conductive coatings in windshields are not only of interest for NIR reflection but these coatings may also be used to provide resistive heating to heat and even defrost windows like windshields and backlights. When buss bars are placed in contact with the conductive layers on PVB, electrical current may be passed through the conductive layers to provide heat. The buss bars may be provided on the PVB which is directly-coated with the conductive layers or buss bars may be provided on the glass to which the directly-coated PVB is adhered in the lamination to glass process. When buss bars are provided on the glass the coated side of directly-coated PVB is bonded directly to the glass so that the buss bars come in contact with the coatings on the PVB. This takes advantage of the remarkable discovery, disclosed herein, that in some cases even the coated side of the PVB can form a bond to glass.

For heated windshields with buss bars on the glass and coated side of the directly-coated PVB in contact with glass, the glass surface that is contacted may optionally be coated with a conductive metal or metal oxide like fluorine doped tin oxide or tin doped indium oxide. These coatings on the glass may complete the dielectric stack of the stack or high index of refraction visible light anti-reflector portion of the coatings of the NIR reflector stack. Thus, for a double metal layer stack, the PVB is directly-coated with, for example, a metal oxide, a metal, a metal nitride and a metal. This stack is then bonded directly to the high index of refraction metal oxide which was previously coated on the glass and helps antireflect the metal layer that contacts the coated glass. Also, the metal oxide that originated on the glass contributes significantly to the overall conductance of stack of layers. Thus better resistive heating is possible since the higher the conductance of the overall stack of conductive layers the more power that can be provided to the windshield at a given voltage.

Preferred NIR-reflecting coatings that are directly-coated on PVB and also lend themselves to the high conductivity that is useful in resistive heating application are the so called IMI coatings disclosed in U.S. Pat. No. 7,830,583, the contents of which are hereby incorporated by reference in their entirety. Also preferred NIR-reflecting coatings which are directly coated on PVB are multi-layer metal oxide systems such as the dielectric mirrors disclosed in U.S. Pat. No. 6,391,400, the contents of which are hereby incorporated by reference in their entirety.

The directly reflective coated PVB may be used in retrofit applications where instead of placing the directly-coated PVB between two other layers of PVB, the coated PVB is bonded on one side to a plastic sheet (e.g., PET or thermoplastic polyurethane) and provided with an adhesive layer on the other side of the coated PVB. This allows the reflective properties to be added to existing windows in buildings or motor vehicles.

For normal application and retrofit applications there are situations in which exposed metal layers like silver metal may corrode or tarnish. Alloys of silver with metals like gold are less vulnerable to corrosion or tarnishing, however there are applications where the edge of the metal layers should not be exposed to the environment. Protecting the edges may be accomplished by trimming the interlayer with a heated knife or cutter which allows the PVB itself to overcoat or seal the edge. In other applications the laminate may be edge sealed via a picture framing method or with materials like epoxies, urethanes, silicones, butyl rubber or polyisobutylene or combinations thereof. Seals and even multiple seals may also be used to protect not only metals that might be used in the reflector but also the PVB itself from moisture, air, and other sources of discoloration and delamination.

### Example 1

Directly-coated PVB was prepared by the following procedure. A 100 micron thick layer of PVB was extrusion cast from PVB resin powder with no plasticizer and no other additives. A roll of this film was directly sputter coated in a roll-to-roll process in low partial pressure of argon in a vacuum chamber. The PVB was directly-coated with a stack of layers consisting of ITO followed by silver metal followed by ITO followed by silver metal followed by ITO. The ITO deposit contained about 90% indium oxide and about 10% tin oxide. The ITO was provided by an indium tin oxide target with a distance of 4 inches between the target and the PVB substrate. The ITO was deposited at a power density of about 2 watts per square centimeter in the presence of a small partial pressure of oxygen, in addition to the argon that was present. The silver was provided by a silver metal target. The stack directly deposited on the PVB was about 300 to 350 angstroms of ITO followed by about 70 to 80 angstroms of silver followed by about 600 to 700 angstroms of ITO followed by about 70 to 80 angstroms and followed by about 300 to 350 angstroms of ITO.

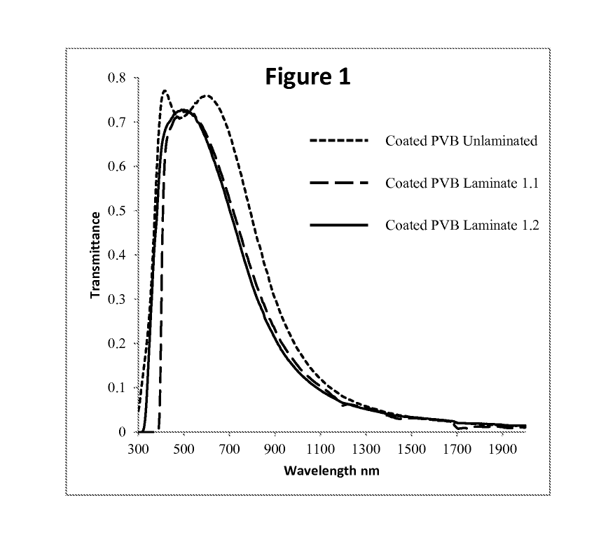

The transmission spectrum for the directly-coated PVB was measured with the directly-coated PVB layer suspended in air. This spectrum is shown in FIG. 1 as the curve with the short dashes (“Coated PVB Unlaminated”). From various spectral measurements of this directly-coated PVB layer the following information was calculated:

| | |
|---|---|
| Emissivity | 0.09 |
| % Total Solar Transmission | 46.7 |
| % Total Solar Reflectance | 35.9 |
| % Total Solar Absorbance | 17.4 |
| % Visible Light Transmission | 71.4 |
| % Visible Light Reflectance | 11.0 |
| % Visible Light Absorbance | 17.6 |
| % Infrared Transmission | 21.3 |
| % Infrared Reflectance | 61.8 |
| % Infrared Absorbance | 16.9 |
| Lightness | L* = 89 |
| Color Coordinates | a* = 1.51 b* = 1.15 |

The spectrum is shown in FIG. 1 for the directly-coated PVB layer of this example, which was laminated between two sheets of 3 millimeter thick clear soda-lime glass with a layer of 750 micron thick plasticized PVB on either side of the directly-coated PVB layer. The spectrum of this laminate is shown as the curve with the long dashes (“Coated PVB Laminate 1.1”). From this spectrum the calculated visible transmission was 62.0% and the calculated solar transmission was 39.3%

The spectrum is also shown in FIG. 1 for the coated PVB which was laminated between two sheets of 3 millimeter thick clear soda-lime glass with two layers of 75 micron thick plasticizer free PVB. This spectrum is shown as the curve with the solid line (“Coated PVB Laminate 1.2”). From this spectrum the calculated visible transmission was 62.8% and the calculated solar transmission was 39.3%

### Example 2

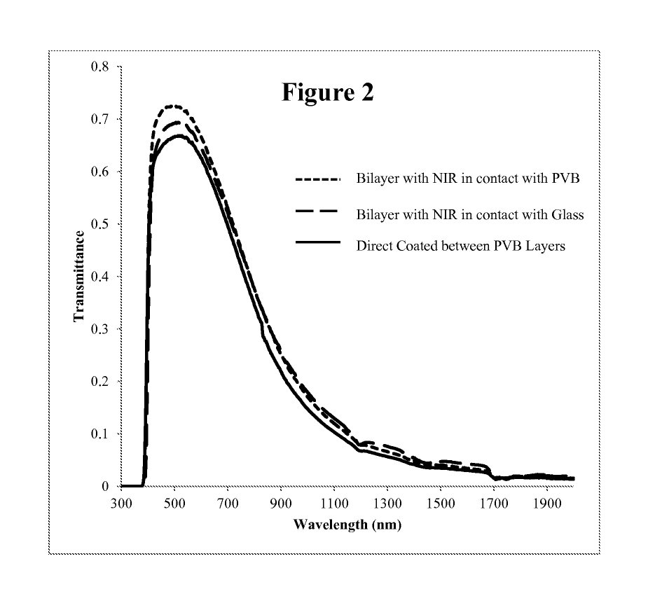

Two bilayers were formed with the coated PVB of Example 1 and layers of plasticized PVB. In FIG. 2, the line with short dashes shows the transmission as a function of wavelength for two sheets of glass laminated together with a bilayer in which the uncoated side of the coated PVB was placed in contact with the glass. In FIG. 2, the line with long dashes shows the transmission as a function of wavelength for two sheets of glass laminated together with a bilayer in which the coated side of the coated PVB was placed in contact with the glass and bonded to the glass. In FIG. 2, the solid line shows the transmission as a function of wavelength for two sheets of glass laminated together with a trilayer in which a layer of coated PVB was placed between two layers of plasticized PVB.

### Example 3

The electrical resistance was measured with a 2 point probe across a sheet of glass coated with transparent conductive layer of fluorine doped tin oxide. The coated sheet of glass was 3 inches by 5 inches and the resistance was 78 ohms with the probes just under 5 inches apart. The coated side of a 3 inch by 4.5 inch piece of the directly-coated PVB of Example 1 was placed with the coated side of this piece of glass. A 3 inch by 4.5 inch sheet of clear uncoated glass was placed on the uncoated side of the directly-coated PVB layer. This assembly was placed in a vacuum bag. The bag was evacuated to a pressure of less than 0.1 torr for one hour. Then the press was heated to 115° C. for 1.25 hours and allowed to cool down for 4 hours. The laminate was removed and the electrical resistance was measured as 69 ohms with the same 2 point probe configuration with the same probe separation of just under 5 inches. Another assembly was prepared in the same manner as above and it was placed in the vacuum bag under vacuum of less than 0.1 torr for 2 hours and then it was heated to 140° C. for 2 hours followed by cooling for 4 hours. The resistance measured in the manner as before was 62 ohms. The combination of the conductive coating which was directly-coated on the PVB and the conductive coating on the glass showed a reduced resistance as compared to the conductive coating on the glass alone.

While the invention has been described in detail with reference to specific embodiments thereof, it will be apparent that numerous modifications and variations are possible without departing from the scope of the teachings disclosed herein.

What is claimed is:

1. A coated PVB film or sheet comprising:
a PVB layer that includes no plasticizer or less than about 5 weight percent of a volatile plasticizer; and
a conductive or reflective coating;
wherein the conductive or reflective coating directly coats the PVB layer.

2. The coated PVB film or sheet of claim 1, wherein the PVB layer includes a non-volatile plasticizer.

3. The coated PVB film or sheet of claim 1, wherein the PVB layer does not include a volatile plasticizer.

4. The coated PVB film or sheet of claim 1, wherein the PVB layer does not include a plasticizer.

5. The coated PVB film or sheet of claim 2, wherein the non-volatile plasticizer is a substituted ammonium or phosphonium salt.

6-8. (canceled)

9. The coated PVB film or sheet of claim 1, wherein the conductive or reflective coating is selected from fluorine doped tin, fluorine doped zinc oxide, tin doped indium oxide, aluminum doped zinc oxide, silver, silver alloys, aluminum, chromium, rhodium and combinations thereof.

10. The coated PVB film or sheet of claim 1, wherein the conductive or reflective coating comprises silver or a silver alloy and a carbide, silicide, boride, nitride, oxide or oxynitride.

11-12. (canceled)

13. A method for coating a PVB film or sheet comprising:
providing a PVB film or sheet that includes little or no volatile material;
in a vacuum, directly applying a conductive or reflective coating to the PVB film or sheet.

14. The method of claim 13, wherein the conductive or reflective coating is deposited on the PVB film or sheet by physical vapor deposition.

15. The method of claim 14, wherein the conductive or reflective coating is deposited on the PVB film or sheet by magnetron sputtering.

16. The method of claim 15, wherein the sputtering is controlled such that the PVB film or sheet temperature remains under 100° C. during the deposition of the conductive or reflective coating.

17. The method of claim 13, wherein the PVB layer includes about 5 weight percent plasticizer or less.

18. The method of claim 13, wherein the PVB layer lacks a plasticizer.

19. The method of claim 13, wherein the PVB layer includes a plasticizer, and wherein the plasticizer is a substituted ammonium or phosphonium salt.

20. A laminate including an interlayer PVB film or sheet with a conductive or reflective coating directly coated thereon, the laminate comprising:
a PVB interlayer film or sheet that includes no plasticizer or less than about 5 weight percent of a volatile plasticizer;
a conductive or reflective coating that directly coats the PVB layer;
a first sheet of glass; and
a second sheet of glass;
wherein the PVB interlayer film or sheet with the conductive or reflective coating directly coated thereon is bonded between the first and second sheets of glass.

21-23. (canceled)

24. The laminate of claim 20, further comprising an adhesive layer.

25-31. (canceled)

32. The laminate of claim 24, wherein the adhesive layer is positioned to bond the PVB interlayer film or sheet with the conductive or reflective coating directly coated thereon to at least one of the first and second sheets of glass in picture frame fashion.

33. The laminate of claim 24 wherein the adhesive layer has a smooth side and textured side.

34-38. (canceled)

39. The laminate of claim 20, wherein the laminate forms at least a portion of a windshield, wherein the conductive or reflective coating is a coating that selectively reflects NIR light, and wherein the laminate further comprises an interlayer with a tint band for the windshield.

40. The laminate of claim 20, wherein a side of the interlayer film or sheet which is coated by the conductive or reflective coating is in contact with a stiff layer selected from the group consisting of a sheet of glass, the coated side of a sheet of glass, and a layer of PVB without plasticizer.

41. The laminate of claim 20, wherein the laminate lacks a PET film layer.

42. The laminate of claim 20, wherein the PVB interlayer film or sheet includes a non-volatile plasticizer, and wherein the non-volatile plasticizer is a substituted ammonium or phosphonium salt.
